(19) United States
(12) Patent Application Publication
(10) Pub. No.: US 2013/0147323 A1
(43) Pub. Date: Jun. 13, 2013

(54) ELECTRONIC DEVICE ENCLOSURE

(71) Applicants: YUN-LUNG CHEN, Tu-Cheng (TW); CHUNG CHAI, Tu-Cheng (TW); DA-LONG SUN, Wuhan City (CN)

(72) Inventors: YUN-LUNG CHEN, Tu-Cheng (TW); CHUNG CHAI, Tu-Cheng (TW); DA-LONG SUN, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/564,269

(22) Filed: Aug. 1, 2012

(30) Foreign Application Priority Data
Dec. 8, 2011 (CN) 201110405496.7

(51) Int. Cl. H05K 5/02

(52) U.S. Cl. 312/223.1

(57) ABSTRACT

A electronic device enclosure includes a rear plate, a side plate attached to the rear plate, and a clipping device. The rear plate includes a blocking tab. The clipping device includes a clipping member and a resilient member. The clipping member is rotatably attached to the side plate and includes an engaging portion engaged with the blocking tab. The resilient member is engaged with the clipping member and the side plate. The clipping member is rotatable relative to the side plate, and the resilient member is deformable to disengage the engaging portion from the blocking tab.

### BACKGROUND

1. Technical Field

The present disclosure relates to enclosures, and more particularly to an electronic device enclosure for securing a side plate to a rear plate.

2. Description of Related Art

An electronic device enclosure, such as a personal computer case, often includes a base and a side plate secured to the base with a plurality of screws. Using screws is very laborious and time-consuming. Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an electronic device enclosure in accordance with an embodiment.

FIG. 2 is an exploded, isometric view of a side plate and a clipping device of FIG. 1.

FIG. 3 is an assembled view of FIG. 2.

FIG. 4 is an isometric view of a clipping member of FIG. 2.

FIG. 5 is similar to FIG. 3, but viewed from a different aspect.

FIG. 6 is an assembled view of FIG. 1.

FIG. 7 is a cross-sectional view of FIG. 6, taken along a line VII-VII, and shows the clipping member in a lock position.

FIG. 8 is similar to FIG. 7, but shows the clipping member in an unlock position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

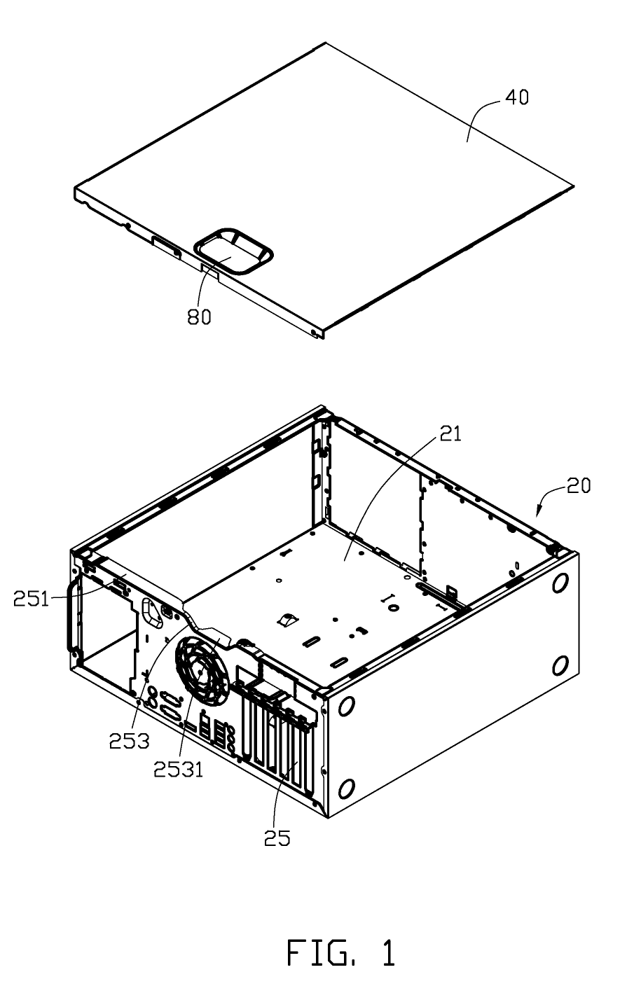

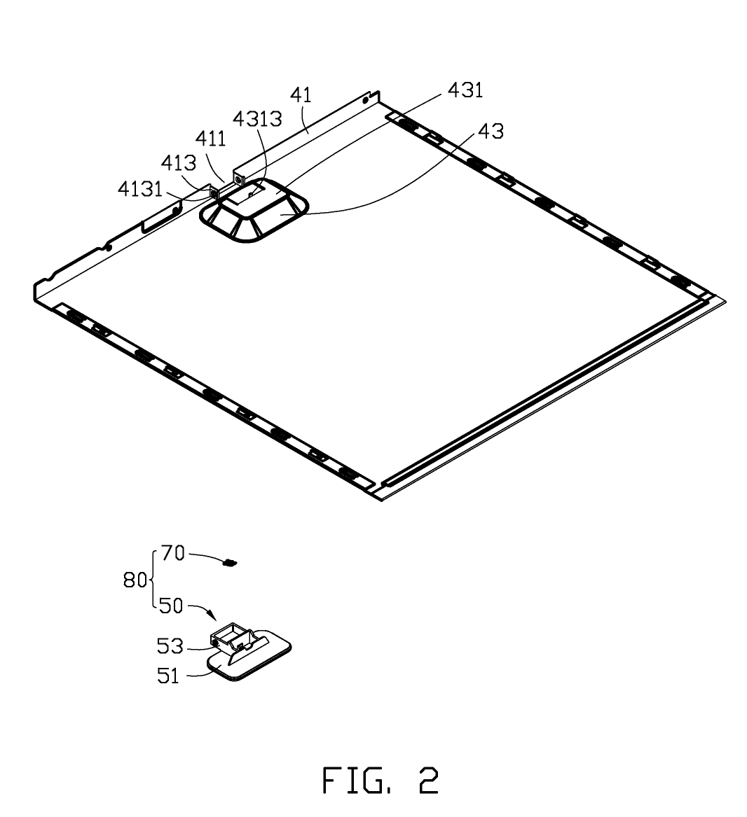

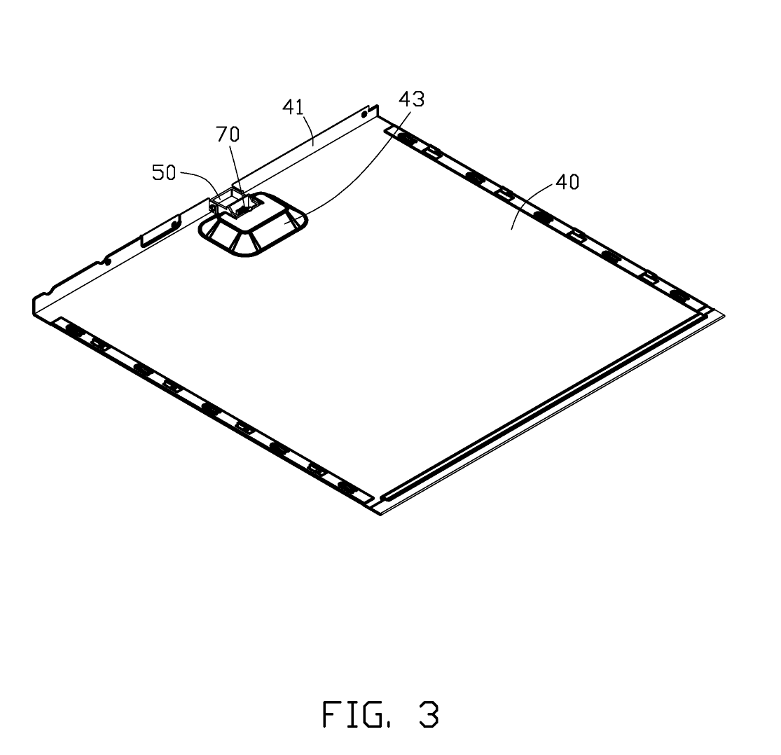

FIGS. 1-3, illustrate an electronic device enclosure in accordance with an embodiment. The electronic device enclosure includes a base 20, a side plate 40 attached to the base 20, and a clipping device 80 rotatably attached to the side plate 40.

The base 20 includes a bottom plate 21 and a rear plate 25 connected to the bottom plate 21. In one embodiment, the rear plate 25 is substantially perpendicular to the bottom plate 21. A rear plate flange 251 extends from a top edge of the rear plate 25, and a concave portion 253 is defined in the rear plate flange 251. A blocking tab 2531 is located on the concave portion 253, and a plane of the blocking tab 2531 is lower than a plane of the rear plate flange 251.

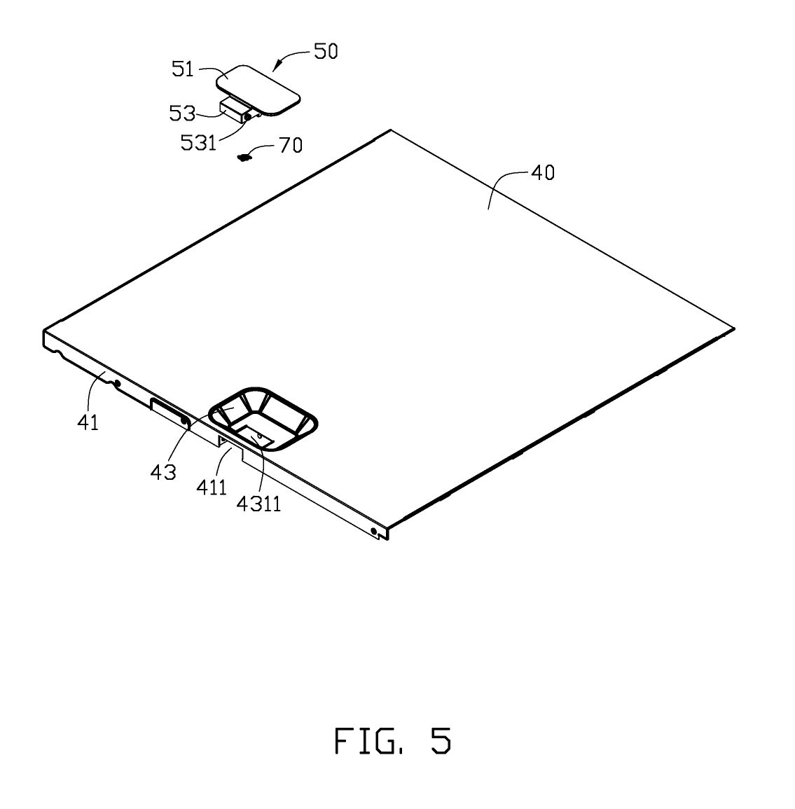

A side plate flange 41 extends from the side plate 40, and an opening 411 is defined in the middle of the side plate flange 41. Two securing pieces 413, each of the two securing pieces 413 with a rotating hole 4131, extend from opposite edges of the opening 411 and towards inside of the side plate flange 41. A mounting portion 43, adjacent to the two securing pieces 413, is defined in the side plate 40. A clipping hole (see FIG. 5) is defined in a bottom portion 431 of the mounting portion 43, and a first hook 4313 is located on the mounting portion 43.

The clipping device 80 includes a clipping member 50 and a resilient member 70. In one embodiment, the resilient member 70 is an extension spring.

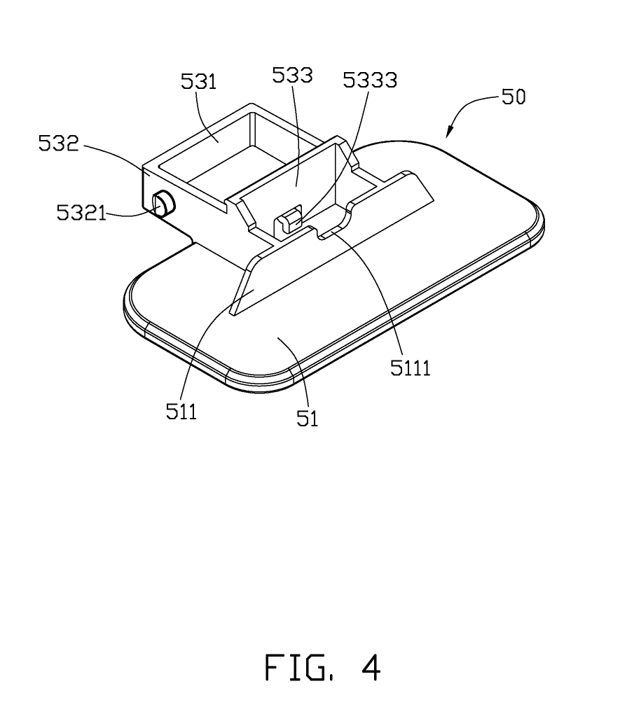

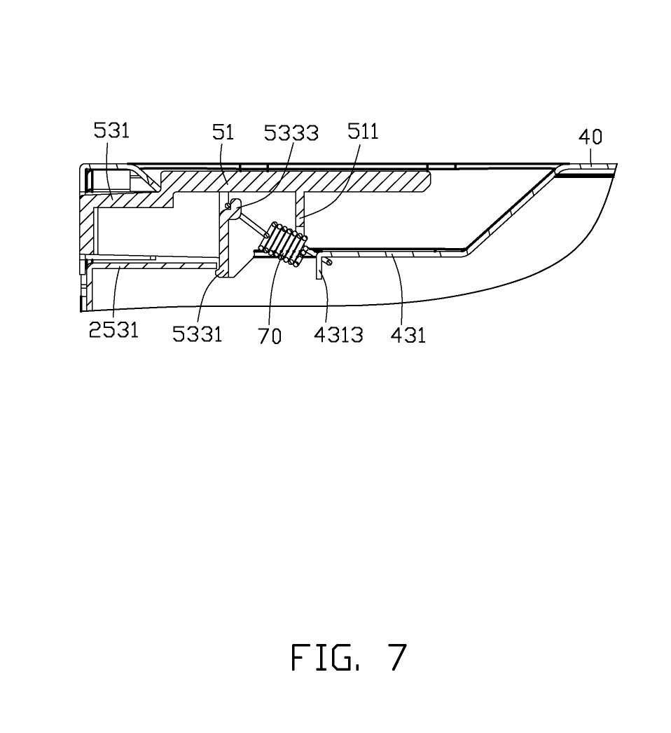

FIG. 4, illustrate the clipping member 50 in accordance with an embodiment. The clipping member 50 includes an operating portion 51 and a rotating portion 53 connected to the operating portion 51. A supporting panel 511 extends from the operating portion 51 and is connected to the rotating portion 53. A cutout 5111 is defined in the supporting panel 511. In one embodiment, the supporting panel 511 is substantially perpendicular to the operating portion 51. A connecting panel 533 is located on the rotating portion 53 and is substantially parallel to the supporting panel 511. An engaging portion 5331 (see FIG. 7) extends from a first side of the connecting panel 533, and a second hook 5333 is located on a second opposite side of the connecting panel 533. The rotating portion 53 is a frame and includes a first panel 531 and two opposite second panels 532. The first panel 531 is substantially parallel to the connecting panel 533, and each of the two opposite second panels 532 is substantially perpendicular to the first panel 531. A rotating post 5321 is located on each of the two second panels 532. In one embodiment, a width of the first panel 531 is substantially equal to a width of the opening 411, so that the first panel 531 can cover the opening 411.

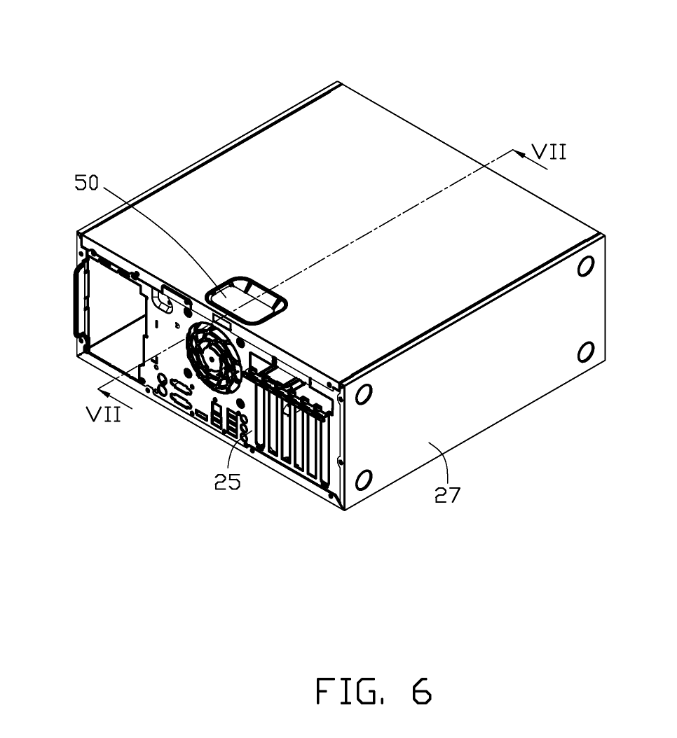

FIGS. 6-8, illustrate an assembly of the electronic device enclosure in accordance with an embodiment. In assembly, the rotating portion 53 extends through the clipping hole 4311, and the operating portion 51 is received in the mounting portion 43. The supporting panel 511 abuts the bottom portion 431, and the cutout 5111 is above the clipping hole 4311. The rotating portion 53 is adjusted to extend the two rotating posts 5321 through the two rotating holes 4131, so that the clipping member 50 is rotatably secured to the two securing pieces 413. A first end of the resilient member 70 is engaged with the first hook 4313, and a second opposite end of the resilient member 70 is engaged with the second hook 5333. Thus, the resilient member 70 is secured to the clipping member 50 and the side plate 40. At this point, the opening 411 is covered by the first panel 531.

The side plate 40 is covered on the base 20, and the side plate flange 41 is aligned with the rear plate flange 251. The operating portion 51 is operated to rotate the clipping member 50 about an axis substantially parallel to the side plate 40 in a first direction. The resilient member 70 is deformed, and the side plate 40 is adjusted to locate the side plate flange 41 on an outside of the rear plate 25. The operating portion 51 is released, and the resilient member 70 is released to move the clipping member 50 in a second direction. The engaging portion 5331 is engaged with the blocking tab 2531 to prevent the side plate 40 disengaging from the rear plate 25, and the rotating portion 53 is received in the concave portion 253. At this point, the clipping member 50 is located in a lock position (see FIG. 7).

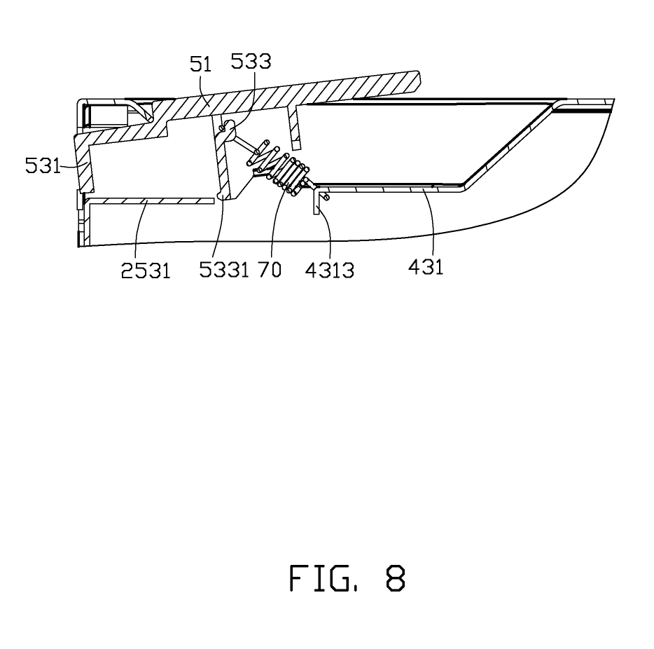

In disassembly, the operating portion 51 is operated to rotate the clipping member 50, and the engaging portion 5331 is disengaged from the blocking tab 2531. At this point, the clipping member 50 is located in an unlock position (see FIG. 8). The side plate 40 is moved and can be detached from the base 20.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device enclosure comprising:
a rear plate comprising a blocking tab;
a side plate attached to the rear plate; and
a clipping device comprising a clipping member and a resilient member; the clipping member is rotatably attached to the side plate and comprising an engaging portion engaged with the blocking tab, and the resilient member engaged with the clipping member and the side plate;
wherein the clipping member is rotatable relative to the side plate, the resilient member is deformable, and the engaging portion is disengaged from the blocking tab.

2. The electronic device enclosure of claim 1, wherein the side plate comprises a first hook engaged with a first end of the resilient member, and the clipping member comprises a second hook engaged with a second opposite end of the resilient member.

3. The electronic device enclosure of claim 2, wherein the side plate comprising a side plate flange; an opening is defined in the side plate flange, a securing piece extends from an edge of the opening, and the clipping member is rotatably secured to the securing piece.

4. The electronic device enclosure of claim 3, wherein the securing piece defines a rotating hole, and the clipping member comprises a rotating post engaged in the rotating hole.

5. The electronic device enclosure of claim 4, wherein the clipping member comprises a rotating portion, the rotating portion comprises a first panel and a second panel that is substantially perpendicular to the first panel, the rotating post is located on the second panel, and the first panel covers the opening.

6. The electronic device enclosure of claim 5, wherein the side plate comprises a mounting portion, the clipping member comprises an operating portion connected to the rotating portion and received in the mounting portion, a clipping hole is defined in the mounting portion, and the rotating portion extends through the clipping hole to rotatably secure to the securing piece.

7. The electronic device enclosure of claim 5, wherein the rotating portion further comprises connecting panel substantially parallel to the first panel, and the second hook and the engaging portion are located on opposite sides of the connecting panel.

8. The electronic device enclosure of claim 6, wherein the operating portion comprises a supporting panel substantially parallel to the first panel, and a cutout is defined in the supporting panel for preventing the resilient member from abutting the supporting panel.

9. The electronic device enclosure of claim 1, wherein the rear plate comprises a rear plate flange, a concave portion is defined in the rear plate flange, and the blocking tab extends from the concave portion and towards inside of the rear plate.

10. The electronic device enclosure of claim 1, wherein a rotating direction of the clipping member is substantially parallel to the side plate.

11. An electronic device enclosure comprising:
an base comprising a rear plate; the rear plate comprising a rear flange; a blocking tab extending from the rear plate flange and towards inside of the base; a plane of the blocking tab being lower than a plane of the rear plate flange;
a side plate attached to the rear plate; and
a clipping device comprising a clipping member and a resilient member; the clipping member is rotatably attached to the side plate and comprising an engaging portion; the resilient member engaged with the clipping member and the side plate;
wherein the clipping member is rotatable relative to the side plate between a lock position and an unlock portion, when the clipping member is located in the lock position, the engaging portion is engaged with the blocking tab; when the clipping member is located in the unlock position, the engaging portion is disengaged from the blocking tab, and the resilient member is deformed.

12. The electronic device enclosure of claim 11, wherein a rotating direction of the clipping member is substantially parallel to the side plate.

13. The electronic device enclosure of claim 11, wherein the side plate comprises a first hook engaged with a first end of the resilient member, and the clipping member comprises a second hook engaged with a second opposite end of the resilient member.

14. The electronic device enclosure of claim 13, wherein the side plate comprising a side plate flange; an opening is defined in the side plate flange, a securing piece extends from an edge of the opening, and the clipping member is rotatably secured to the securing piece.

15. The electronic device enclosure of claim 14, wherein the securing piece defines a rotating hole, and the clipping member comprises a rotating post engaged in the rotating hole.

16. The electronic device enclosure of claim 15, wherein the clipping member comprises a rotating portion, the rotating portion comprises a first panel and a second panel that is substantially perpendicular to the first panel, the rotating post is located on the second panel, and the first panel covers the opening.

17. The electronic device enclosure of claim 16, wherein the side plate comprises a mounting portion, the clipping member comprises an operating portion connected to the rotating portion and received in the mounting portion, a clipping hole is defined in the mounting portion, and the rotating portion extends through the clipping hole to rotatably secure to the securing piece.

18. The electronic device enclosure of claim 16, wherein the rotating portion further comprises a connecting panel substantially parallel to the first panel, and the second hook and the engaging portion are located on opposite sides of the connecting panel.

19. The electronic device enclosure of claim 17, wherein the operating portion comprises a supporting panel substantially parallel to the first panel, and a cutout is defined in the supporting panel for preventing the resilient member from abutting the supporting panel.

20. The electronic device enclosure of claim 11, wherein the resilient member is an extension spring.
